(19) United States
(12) Patent Application Publication
(10) Pub. No.: US 2024/0306557 A1
(43) Pub. Date: Sep. 19, 2024

(54) DEVICE FOR PROMOTING PLANT GROWTH

(71) Applicant: GroBud Pty Ltd, Melbourne (AU)

(72) Inventors: Mark Dansie, San Jose del Monte (PH); Ian Mabolo, San Jose del Monte (PH)

(21) Appl. No.: 18/681,253

(22) PCT Filed: Aug. 11, 2022
(86) PCT No.: PCT/AU2022/050879

§ 371 Date: Feb. 5, 2024

(30) Foreign Application Priority Data
Aug. 11, 2021 (AU) 2021902491

(51) Int. Cl. A01G 7/04

(52) U.S. Cl. CPC A01G 7/04

(57) ABSTRACT

This invention preferably relates to a solar-powered device comprising a corrosion-resistant graphite rods as electrodes. The graphite rods are configured for insertion into soil such that an electric charge may be applied to the soil to promote plant growth.

### CROSS-REFERENCE TO RELATED APPLICATION(S)

This application is a Section 371 National Stage Application of International Application No. PCT/AU2022/050879, filed Aug. 11, 2022 and published as WO 2023/015351 A1, in English, and claims priority to Australian provisional patent application no. 2021902491, filed Aug. 11, 2021.

### FIELD OF THE INVENTION

The present invention is generally directed to a device for applying an electric current to plants to promote plant growth and yield.

### BACKGROUND TO THE INVENTION

Plant growth primarily relies on the efficiency of the roots to absorb nutrients present in the soil. The use of chemical fertilizers has been a standard practice among farmers seeking to boost crop production and yield; while the use of pesticides and insecticides have become usual practice in getting rid of insects and pests that would otherwise attack crops.

With recent global trends directed toward utilising sustainable farming and agriculture practices, new methods of increasing crop yield are required, particularly those not necessarily involving fertilizers and pesticides.

The study of electroculture to promote plant growth by subjecting plants to electric fields and/or electric currents has been around for some time. FIG. 1 shows an electroculture device, as published in Yi, et al., “Effects of a low-voltage electric pulse charged to culture soil on plant growth and variations of the bacterial community”. Agricultural Sciences, Vol. 3(3), (2012) pp 339-346 (the entire disclosure of which is hereby incorporated by reference). Yi teaches that an electric pulse may be generated between an anode and cathode by periodic exchange of DC electrode poles. The taught electroculture device includes a power source 202, a first electrode 204 connected to the power source 202 via a wire 208, a second electrode 206 connected to the power source 202 via another wire 210, and plants 212 located in soil between electrodes. In the device taught in Yi, titanium sheets or plates, each being 1000 mm long. 200 mm high and 1 mm wide, are positioned 120 mm apart, are used as the respective electrodes, and direct current electric pulses of 2, 4, 6, 8, or 10V are supplied to the electrodes with plant root-stock located between the electrodes. According to Yi, the generated electric charges may influence the physiology of microorganisms, the behaviour of ionic compounds, and the oxidation-reduction potential. Results of the experiment showed that growth and fruiting duration of plants was activated and increased.

Devices similar to that disclosed in Yi have been produced, with the metals used to produce electrodes including: copper, silver and brass. These metals are subject to oxidation resistance and corrosion, particularly given their use in moist soils for the purposes of plant growth. The corrosion of the electrodes in many devices increases electrical resistance, thereby reducing the electrical efficiency of the device. Where corrosion is extreme, this could result in total failure to apply an electrical charge to the soil. Other metals, including titanium, platinum and palladium exhibit high corrosion resistance and may be used as alternative electrodes, but these materials are very expensive.

It would be desirable to provide a cost effective and resilient device suitable for supplying an electric charge to a soil to promote plant growth, the device facilitating ease of transport and installation in remote locations.

The reference in this specification to any prior publication, or information derived from it, or to any matter which is known, is not, and should not be taken as an acknowledgement or admission or any form of suggestion that the prior publication, or information derived from it, or known matter forms part of the common general knowledge in the field of endeavour to which this specification relates.

### SUMMARY OF THE INVENTION

According to a first aspect of the invention, there is provided a device for applying an electric charge into soil to promote plant growth, the device comprising a power source and two electrodes formed of non-metallic conductive material.

In an embodiment, the electrodes are formed of a conductive carbon-based material.

In an embodiment, the electrodes are formed of graphite.

In an embodiment, the graphite has a bulk density of at least 1.5 g/cm³.

In an embodiment, each of the electrodes has a specific resistance in the range of 7-15 μΩ·m.

In an embodiment, each of the electrodes has a shore hardness in the range of 20-80.

In an embodiment, each of the electrodes has a bending strength of greater than 45 MPa.

In an embodiment, each of the electrodes has a compressive strength greater than 65 MPa.

In an embodiment, each of the electrodes is configured for to be driven into the ground.

In an embodiment, each electrode is configured as a rod.

In an embodiment, each electrode comprises a tapered end to facilitate being driven into the ground.

In an embodiment, each electrode is between 50 mm and 400 mm long.

In an embodiment, each electrode extends from a common joining member or joining assembly.

In an embodiment, the electrodes are arranged less than 120 mm apart from one another.

In an embodiment, the electrodes are configured to support the power source in position above ground in use.

In an embodiment, the device is configured to be carried in one hand during transport.

In an embodiment, the power source comprises a solar panel for generating electricity.

In an embodiment, the solar panel has a first width of between 50-100 mm and a second width between 50-100 mm.

In an embodiment, the solar panel has an output voltage of approximately 5V and an output current of approximately 100 mA.

In an embodiment, the device is configured to enable the solar panel to be tilted relative to the ground when installed.

In an embodiment, each of the electrodes is electrically connected to the power source via wires to form an electrode wire system.

In an embodiment, the electrode wire system is isolated and sealed in an enclosure.

In an embodiment, the device is configured to be carried in one hand during transport.

In an embodiment, the device is configured to be carried in hand by holding onto the enclosure.

In an embodiment, the electrodes each extend from the enclosure.

In an embodiment, the electrodes extend from the enclosure at a distance of less than 120 mm apart from one another.

In an embodiment, the device is configured to apply voltages between 3V and 5V DC with current between 5 mA and 50 mA in either a continuous or pulsating manner.

According to a second aspect of the invention, there is provided use of the device to promote plant growth by applying an electric charge to the ground.

The present summary is provided only by way of example and not limitation. Other aspects of the present invention will be appreciated in view of the entirety of the present disclosure, including the entire text, claims, and accompanying figures.

Throughout this specification and the claims which follow, unless the context requires otherwise, the word “comprise” and variations thereof such as “comprises” and “comprising”, will be understood to include the inclusion of a stated integer or step or group of integers or steps but not the exclusion of any other integer or step or groups of integers or steps.

### BRIEF DESCRIPTION OF THE FIGURES

FIG. 1 shows electroculture systems according to the prior art.

FIG. 2 shows a device according to an embodiment of the invention.

FIG. 3 shows the device of FIG. 2 in use.

While the above-identified figures set forth one or more embodiments of the present invention, other embodiments are also contemplated, as noted in the discussion. In all cases, this disclosure presents the invention by way of representation and not limitation. It should be understood that numerous other modifications and embodiments can be devised by those skilled in the art, which fall within the scope and spirit of the principles of the invention. The figures may not be drawn to scale, and applications and embodiments of the present invention may include features, steps, and/or components not specifically shown in the drawings.

### REFERENCE NUMERALS

10 solar panel
20 panel enclosure
30 joining element/wire enclosure
40 tilt knob
50 electrodes
60 soil bed

### DETAILED DESCRIPTION OF THE INVENTION

In general terms, the invention as detailed relates to a device to promote plant growth via applying an electric charge to soil and use of such a device to promote plant growth via applying an electric charge to soil.

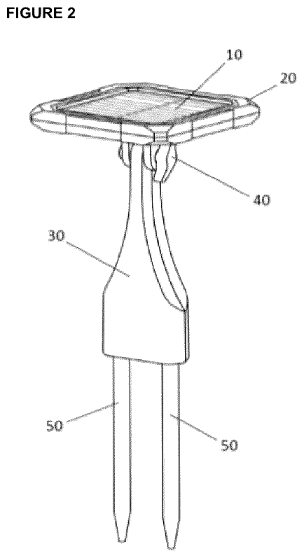

With reference to FIG. 2, an embodiment of the invention will now be described.

FIG. 2 shows a device for applying an electric charge to soil. The device includes a power source and electrodes formed of non-metallic conductive material.

Non-metallic conductive materials generally provide the advantage of low corrosion characteristics. In the embodiment shown, the electrodes are formed of graphite. In alternative embodiments, the electrodes may for example be formed of conductive polymers such as polyacetylene, polyaniline, or polypyrrole.

Graphite has been identified as particularly suitable alternative to current technologies utilising metal electrodes, since:
graphite is inert and therefore resistant to corrosion. In wet or dry soil, graphite rods will allow the electricity to flow efficiently from the source to the soil and ensures efficient delivery of electricity into the soil to stimulate the roots of plants for better crop yields.
graphite performs well even at high current densities and has good conductivity due to its very low specific resistance; and
graphite is relatively cost-effective when compared with precious metals such as platinum and palladium.

In the embodiment shown, the electrodes are formed as rods suitable to be driven into the ground and include tapered ends or tips assisting such insertion. In this way, the electrodes may be pushed or driven into the ground for installation and the device is then held in place in the soil, while the electrodes are positioned to apply an electrical charge deep into the soil.

In the embodiment shown, the device is configured to be carried in one hand during transport whereby the device may be easily transported and installed simply by driving the electrodes into the ground as discussed above. In this way, a number of like devices may be installed quickly and simply in a field, garden bed or similar. This contrasts with the device of Yi, which required a garden bed to be dug out before each electrode may be installed, with plants to be located between corresponding electrodes.

According to embodiments of the invention (including the embodiment shown in FIG. 2), the electrodes provide one or more of the following characteristics:
a bulk density of not less than 1.5 g/cm³;
a specific resistance range of 7-15 μΩ·m;
a Shore hardness range of 20-80;
a bending strength of greater than 45 MPa; and
a compressive strength of greater than 65 MPa. Without wishing to be bound by theory, it is believed that the above characteristics, may, for example, provide sufficient strength to enable insertion into many soils without breaking, and provide sufficient electrical conductivity to suitably apply an electrical charge to a soil, thereby promoting plant growth.

Any power source suitable for enabling the electrodes to apply an electrical charge to soil may be utilised according to the invention. According to embodiments of the invention, the power source may include: mains power, batteries, wind powered devices, and solar panels. In the embodiment shown, the device is powered by a solar panel 10. Where mains power is applied, the device may according to certain embodiments include a rectifier enabling conversion from AC to DC and other required components to supply electricity at an appropriate voltage and current.

The use of a solar panel advantageously enables use of the device in any location providing sufficient sunshine, without, for example, having to supply mains electricity or otherwise recharge a battery from time to time. A solar panel therefore enables flexibility of use while also being environmentally friendly, though taking advantage of renewable energy. Further solar powered devices enable fast and simple installation of multiple devices without having to arrange for connection to mains electricity and the like. Rather, the installation of devices according to embodiments of the invention may simply involve driving electrodes of the device into the ground.

In the embodiment of the invention shown, the solar panel has a first width of 70 mm and a second width of 70 mm. The power rating of the solar panel is 0.5 W and it provides an output voltage of 5V and output current of 100 mA. A solar panel provided in accordance with the above will provide sufficient power to apply an electrical field to soil to yield enhancement of nearby plant growth.

In an embodiment of the invention, the electrodes are directly wired to the solar panel. In an alternative embodiment, the power source may, for example, further include a battery for storing power derived from the solar panel, thereby enabling the device to store power for use when there is insufficient sunshine (e.g. cloudy days and at night). In the embodiment shown, the electrodes are directly wired to the solar panel and the wires are housed in a wire enclosure, also known as a joining element, as now described.

According to embodiments of the invention, the solar panel is housed in a panel enclosure 20 and the wires connecting the electrodes to the solar panel are housed in a wire enclosure/joining element 30 for protection from the elements and to, for example, prevent shorting of the device. Each of the panel enclosure 20 and the wire enclosure/joining element 30 may be formed of a plastic polymer. Optionally, the plastic polymer is a UV resistant thermoplastic, such as ABS, so as to improve the ability of the device to withstand weather over time. In the embodiment shown, the joining element 30 joins the electrodes 50 to the panel enclosure 20. Electrodes 50 extend from the joining element 30 in a manner such that the electrodes 50 may support the solar panel 20 above the ground. That is, in the embodiment shown, providing a rigid casing for the wires (i.e. wire enclosure 30) connecting the panel enclosure 20 to the electrodes 50 provides certain advantages including:
that the device may carried and transported simply and easily in one hand, for example by holding onto the joining element 30;
that the electrodes 50 of the device may be driven into the ground in a single action; for example while holding onto the joining element 30;
where the device includes solar power, the electrodes 50 may support the solar panel enclosure 20 in a manner enabling the solar panel to face the sun (and in certain embodiments tilted; as discussed below) and
electrical wiring is protected from the elements and manual handling.

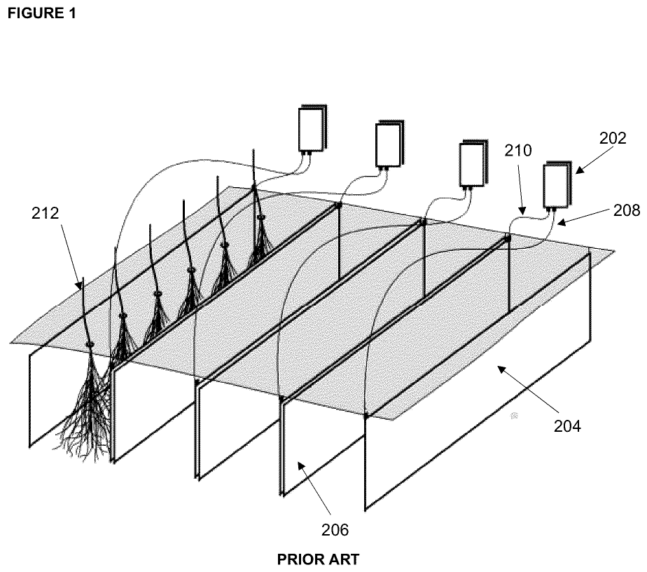

Unlike the device disclosed in YI, the electrodes are not configured such that plants must necessarily be placed between the two electrodes (see FIG. 1). Rather, in the embodiments shown, the electrodes 50 are provided as rods arranged less than 120 mm apart. Without wishing to be bound by theory, it is understood that the charge and current provided by the electrodes 50 will extend about the device to contribute to the growth of nearby plants.

To ensure optimum operation of the device (in embodiments of the invention where the device includes a solar panel), the solar panel may be tilted relative to the ground to ensure optimum position of the solar panel relative to the sun. In the embodiment shown, the device includes a solar head tilt knob 40 which, when loose, enables the solar panel to be tilted and, when tightened, holds the solar panel in a fixed position. In the embodiment shown, the solar head tilt knob 40 connects the solar panel enclosure 20 to the wiring enclosure 30.

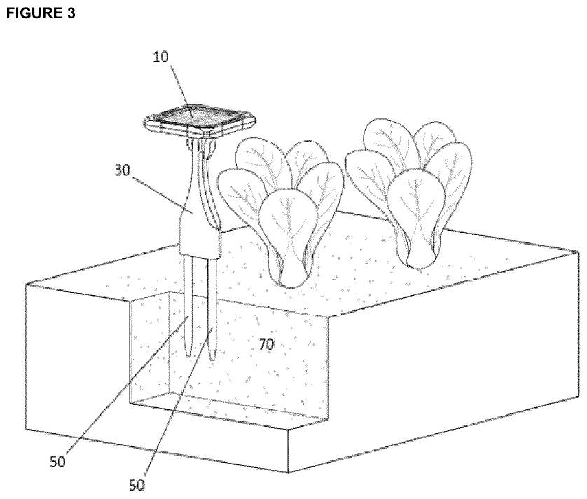

FIG. 3 shows the device of FIG. 2 installed in a soil bed 70. As discussed above, the device may according to certain embodiments be configured such that the electrodes 50 may be pushed or driven into the soil bed 70 in a single action (such as while holding onto the wiring enclosure 30), enabling a charge to be applied to the soil bed through the electrodes.

The use of appropriate graphite rods and adequate amount of voltage being delivered into the soil bed will ensure that a suitable amount of current will be created to stimulate plant root systems.

The graphite rod of adequate specific resistance facilitates the delivery of currents in the range of 5 mA and 50 mA as supplied by the 0.5 W-solar panel into the soil. The small amounts of current delivered to the soil, either in continuous mode or pulsating manner, as mentioned by Yi et al, facilitates the enhancements during plant growth through its root systems.

Without wishing to be bound by theory, it is believed that the application of an electric field in accordance with the above will promote plant growth by introducing small amounts of current into the soil. The generated electric charges may then influence the physiology of microorganisms, the behaviour of ionic compounds, and the oxidation-reduction potential of the soil.

Throughout this specification and the claims which follow, unless the context requires otherwise, the word “comprise” and variations thereof such as “comprises” and “comprising”, will be understood to include the inclusion of a stated integer or step or group of integers or steps but not the exclusion of any other integer or step or groups of integers or steps.

To those skilled in the art to which the invention relates, many changes in construction and widely differing embodiments and applications of the present invention will suggest themselves without departing from the scope of the present invention as defined in the appended claims. The disclosures and the descriptions herein are purely illustrative and are not intended to be in any sense limiting.

1. A device for applying an electric charge into soil to promote plant growth, the device comprising a power source and two electrodes formed of non-metallic conductive material.

2. The device according to claim 1, wherein the electrodes are formed of a conductive carbon-based material.

3. The device according to claim 2, the electrodes are formed of graphite.

4. The device according to claim 3, wherein the graphite has a bulk density of at least 1.5 g/cm³.

5. The device according to claim 1, wherein each of the electrodes has a specific resistance in a range of 7-15 μΩ·m.

6. The device according to claim 1, wherein each of the electrodes has a shore hardness in a range of 20-80.

7. The device according to claim 1, wherein each of the electrodes has a bending strength of greater than 45 MPa.

8. The device according to claim 1, wherein each of the electrodes has a compressive strength greater than 65 MPa.

9. The device according to claim 1, wherein each of the electrodes is configured to be driven into the ground.

10. The device according to claim 1, wherein each electrode is configured as a rod.

11. The device according to claim 1, wherein each electrode comprises a tapered end to facilitate being driven into the ground.

12. The device according to claim 1, wherein each electrode is between 50 mm and 400 mm long.

13. The device according to claim 1, wherein each electrode extends from common joining member or joining assembly.

14. The device according to claim 1, wherein the electrodes are arranged less than 120 mm apart from one another.

15. The device according to claim 1, wherein the electrodes are configured to support the power source in position in use.

16. The device according to claim 1, wherein the device is configured to be carried in one hand during transport.

17. The device according to claim 1, wherein the power source comprises a solar panel for generating electricity.

18. The device according to claim 17, wherein the solar panel has a first width of between 50-100 mm and a second width between 50-100 mm.

19. The device according to claim 17, wherein the solar panel has an output voltage of approximately 5V and an output current of approximately 100 mA.

20. The device according to claim 17, wherein the device is configured to enable the solar panel to be tilted relative to the ground when installed.

21. The device according to claim 1, wherein each of the electrodes is electrically connected to the power source via wires to form an electrode wire system.

22. The device according to claim 21, wherein the electrode wire system is isolated and sealed in an enclosure.

23. (canceled)

24. The device according to claim 22, wherein the device is configured to be carried in hand by holding onto the enclosure.

25. The device according to claim 22, wherein the electrodes each extend from the enclosure.

26. The device according to claim 25, wherein the electrodes extend from the enclosure at a distance of less than 120 mm apart from one another.

27. The device according to claim 1, wherein the device is configured to apply voltages between 3V and 5V DC with current between 5 mA and 50 mA in either a continuous or pulsating manner.

28. A method of using the device according to claim 1 to promote plant growth by applying an electric charge to the ground.
